(19) United States
(12) Patent Application Publication
(10) Pub. No.: US 2026/0293011 A1
(43) Pub. Date: Sep. 24, 2026

(54) DISPLAY DEVICE

(71) Applicant: LG ELECTRONICS INC., Seoul (KR)

(72) Inventors: Jinmyung OH, Seoul (KR); Jaegi LEE, Seoul (KR); Sejin KWON, Seoul (KR); Hyuncheol CHO, Seoul (KR); Munhwan KIM, Seoul (KR)

(73) Assignee: LG ELECTRONICS INC., Seoul (KR)

(21) Appl. No.: 19/534,221

(22) Filed: Feb. 9, 2026

(30) Foreign Application Priority Data
Mar. 18, 2025 (WO) PCT/KR2025/003526

(51) Int. Cl. H05K 5/02

(52) U.S. Cl. CPC H05K 5/0247; H05K 5/0204; H05K 5/0217

(57) ABSTRACT

A display device is disclosed. The display device may include: a display; a pair of mounts coupled to a rear of the display; a bracket positioned behind the display and spaced apart from the pair of mounts; and a pair of wires connecting the pair of mounts and the bracket, wherein the bracket may include: a base; a pair of first coupling portions protruding from the base toward the display and spaced apart from each other by a first distance in a horizontal direction; and a pair of second coupling portions protruding from the base toward the display and spaced apart from each other by a second distance greater than the first distance in the horizontal direction, and wherein: a portion of each of the pair of first coupling portions may be bent in a first direction with respect to a vertical direction; a portion of each of the pair of second coupling portions may be bent in a second direction opposite to the first direction with respect to the vertical direction; and the pair of wires may be engaged with the pair of first coupling portions or the pair of second coupling portions.

### CROSS-REFERENCE TO RELATED APPLICATION

Pursuant to 35 U.S.C. § 119, this application claims the benefit of earlier filing date and right of priority to International Application No. PCT/KR2025/003526, filed on Mar. 18, 2025, the contents of which are all incorporated by reference herein in their entirety.

### BACKGROUND OF THE INVENTION

### Field of the invention

The present disclosure relates to a display device.

### Description of the Related Art

With the development of information society, there has been a growing demand for various types of display devices. In order to meet such demand, various display devices, such as a liquid crystal display (LCD) device, a plasma display panel (PDP), an electro luminescent display (ELD), a vacuum fluorescent display (VFD), an organic light emitting diode (OLED) display device, and the like, have been developed and used.

Among them, an LCD panel includes a TFT substrate and a color substrate that are opposite each other with a liquid crystal layer interposed therebetween, and can display an image using light provided from a backlight unit. In addition, an OLED panel can display an image by depositing a self-luminescent organic layer on a substrate having a transparent electrode formed thereon.

Meanwhile, in line with recent trends in the development and consumption patterns of display devices, research on a structure for mounting a display device on a wall has been intensively conducted.

### SUMMARY OF THE INVENTION

It is an object of the present disclosure to solve the above and other problems.

Another object of the present disclosure may be to provide a structure capable of installing displays of different sizes on a fixed object such as a wall using a single bracket.

Another object of the present disclosure may be to provide a bracket assembly capable of corresponding to VESA holes at various intervals.

Another object of the present disclosure may be to provide a bracket capable of being secured to a fixed object such as a wall at various positions.

Another object of the present disclosure may be to provide a structure capable of minimizing tilting of a wire relative to a bracket.

Another object of the present disclosure may be to provide a structure capable of minimizing tilting of a mount and a display relative to a bracket.

Another object of the present disclosure may be to provide a structure capable of adjusting the left-right tilt of a display installed on a fixed object such as a wall.

In accordance with an aspect of the present disclosure for achieving the above and other objects, a display device may include: a display; a pair of mounts coupled to a rear of the display; a bracket positioned behind the display and spaced apart from the pair of mounts; and a pair of wires connecting the pair of mounts and the bracket, wherein the bracket may include: a base; a pair of first coupling portions protruding from the base toward the display and spaced apart from each other by a first distance in a horizontal direction; and a pair of second coupling portions protruding from the base toward the display and spaced apart from each other by a second distance greater than the first distance in the horizontal direction, and wherein: a portion of each of the pair of first coupling portions may be bent in a first direction with respect to a vertical direction; a portion of each of the pair of second coupling portions may be bent in a second direction opposite to the first direction with respect to the vertical direction; and the pair of wires may be coupled to the pair of first coupling portions or the pair of second coupling portions.

In accordance with another aspect of the present disclosure, a bracket assembly may include: a pair of mounts; a bracket spaced apart from the pair of mounts; and a pair of wires connecting the pair of mounts and the bracket, wherein the bracket may include: a base; a pair of first coupling portions protruding from one surface of the base and spaced apart from each other by a first distance in a horizontal direction; and a pair of second coupling portions protruding from the one surface of the base and spaced apart from each other by a second distance greater than the first distance in the horizontal direction, and wherein a portion of each of the pair of first coupling portions may be bent in a first direction with respect to a vertical direction, and a portion of each of the pair of second coupling portions may be bent in a second direction opposite to the first direction with respect to the vertical direction.

In accordance with another aspect of the present disclosure, a display device may include: a display; a pair of mounts coupled to a rear of the display; a bracket positioned behind the display and spaced apart from the pair of mounts; and a pair of wires connecting the pair of mounts and the bracket, wherein the bracket may include: a base; a pair of first coupling portions protruding from the base toward the display and spaced apart from each other by a first distance in a horizontal direction; and a pair of second coupling portions protruding from the base toward the display and spaced apart from each other by a second distance greater than the first distance in the horizontal direction.

### BRIEF DESCRIPTION OF THE DRAWINGS

The above and other objects, features and advantages of the present invention will be more apparent from the following detailed description in conjunction with the accompanying drawings, in which:

FIGS. 1 to 25 are diagrams illustrating examples of a display device according to embodiments of the present disclosure.

### DETAILED DESCRIPTION

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated.

In the following description, a suffix such as “module” and “unit” may be used to refer to elements or components. Use of such a suffix herein is merely intended to facilitate description of the specification, and the suffix itself is not intended to give any special meaning or function.

In the present disclosure, that which is well known to one of ordinary skill in the relevant art has generally been omitted for the sake of brevity. The accompanying drawings are used to help easily understand various technical features and it should be understood that the embodiments disclosed herein are not limited by the accompanying drawings. As such, the present disclosure should be construed to extend to any alterations, equivalents, and substitutes in addition to those which are particularly set out in the accompanying drawings.

Although the terms “first”, “second”, etc. may be used herein to describe various elements, these elements should not be limited by these terms. These terms are only used to distinguish one element from another.

It will be understood that when a component is referred to as being “coupled”, “fixed”, “mounted”, “connected” or “linked” to another component, it may be directly coupled or connected to another component, or intervening components may be present. In contrast, when a component is referred to as being “directly coupled”, “directly fixed”, “directly mounted”, “directly connected” or “directly linked” to another component, there are no intervening components present.

A singular representation may include a plural representation unless the context clearly indicates otherwise.

Terms such as “comprises or includes” or “has” are used herein and should be understood that they are intended to indicate an existence of features, numbers, steps, operations, elements, components, or combinations thereof, disclosed in the specification, but do not preclude the presence or addition of one or more other features, numbers, steps, operations, elements, components, or combinations thereof.

The directions “up (U)”, “down (D)”, “left (Le)”, “right (Ri)”, “front (F)”, and “rear (R)” shown in the drawings are provided for convenience of description only, and the technical concept disclosed in this specification is not limited by these directions.

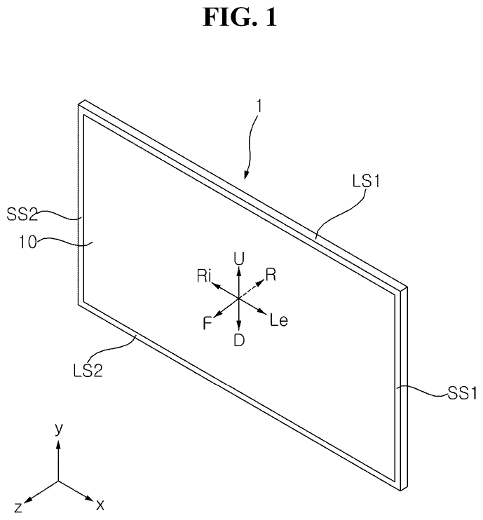

Referring to FIG. 1, a display device 1 may include a display panel 10. The display panel 10 may display an image.

The display device 1 may include a first long side LS1, a second long side LS2 opposite the first long side LS1, a first short side SS1 adjacent to the first long side LS1 and the second long side LS2, and a second short side SS2 opposite the first short side SS1. Meanwhile, for ease of explanation, it is illustrated and described that lengths of the first and second long sides LS1 and LS2 are greater than lengths of the first and second short sides SS1 and SS2, but the lengths of the first and second long sides LS1 and LS2 may be substantially equal to the lengths of the first and second short sides SS1 and SS2.

A direction parallel to the long sides LS1 and LS2 of the display device 1 may be referred to as a left-right direction. A direction parallel to the short sides SS1 and SS2 of the display device 1 may be referred to as an up-down direction. A direction perpendicular to the long sides LS1 and LS2 and the short sides SS1 and SS2 of the display device 1 may be referred to as a front-rear direction.

A direction in which the display panel 10 displays an image may be referred to as a front (F, z), and a direction opposite to the front may be referred to as a rear (R). The first long side LS1 may be referred to as an upper side (U, y), and the second long side LS2 may be referred to as a lower side (D). The first short side SS1 may be referred to as a left side (Le, x), and the second short side SS2 may be referred to as a right side (Ri).

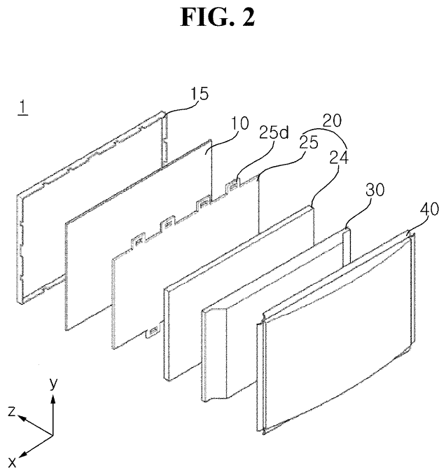

Referring to FIG. 2, the display device 1 may include a display panel 10, a front cover 15, a backlight unit 20, a frame 30, and a back cover 40.

The display panel 10 may form a front surface of the display device 1, and may display an image. The display panel 10 may display an image in such a manner that each of a plurality of pixels outputs red, green or blue (RGB) light in accordance with timing. The display panel 10 may be divided into an active area in which an image is displayed and a de-active area in which no image is displayed. The display panel 10 may include a front substrate and a rear substrate that are opposite each other with a liquid crystal layer interposed therebetween. The display panel 10 may be referred to as an LCD panel.

The front substrate may include a plurality of pixels, each of which consists of red, green, and blue sub-pixels. The front substate may output light corresponding to red, green or blue color in response to a control signal.

The rear substrate may include switching elements. The rear substrate may switch a pixel electrode. For example, the pixel electrode may change the molecular arrangement of a liquid crystal layer in response to a control signal input from the outside. The liquid crystal layer may include liquid crystal molecules. The arrangement of the liquid crystal molecules may be changed according to a voltage difference between the pixel electrode and a common electrode. The liquid crystal layer may transmit light provided from the backlight unit 20 to the front substrate or block the light.

The front cover 15 may cover at least a portion of the front and side surfaces of the display panel 10. The front cover 15 may be omitted.

The backlight unit 20 may be positioned at the rear of the display panel 10. The backlight unit 20 may be coupled to the front of the frame 30. The back light unit 20 may include light sources configured to provide light to the display panel 10. The backlight unit 20 may include an optical sheet 25 and an optical layer 24.

The optical sheet 25 may allow light from the light source to be uniformly transmitted to the display panel 10. For example, the optical sheet 25 may include a prism sheet, a diffusion sheet, and the like. The optical sheet 25 may include a coupling portion 25d. The coupling portion 25d may be coupled to the front cover 15, the frame 30, and/or the back cover 40.

The frame 30 may be positioned behind the display panel 10 so as to support components of the display device 1. For example, the backlight unit 20 and a printed circuit board (PCB) on which a plurality of electronic elements are disposed may be coupled to the frame 30.

The back cover 40 may be coupled to the rear of the frame 30. The back cover 40 may form a rear surface of the display device 1.

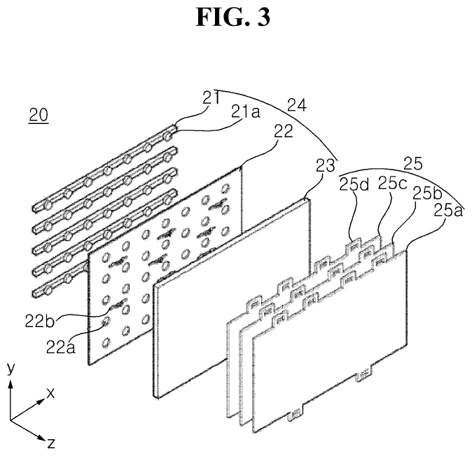

Referring to FIG. 3, the backlight unit 20 may include an optical layer 24 including a substrate 21, at least one light assembly 21a, a reflective sheet 22, and a diffusion plate 23, and an optical sheet 25 positioned at the front of the optical layer 24.

The substrate 21 may be elongated. A plurality of substrates 21 may be spaced apart from each other. At least one light assembly 21a may be mounted on the substrate 21. An electrode pattern for connecting an adapter and the light assembly 21a may be formed on the substrate 21. The substrate 21 may be made of at least one of polyethylene terephthalate (PET), glass, polycarbonate (PC), and silicon. The substrate 21 may be a printed circuit board (PCB) on which at least one light assembly 21a is mounted.

The light assembly 21a may be a light emitting diode (LED) chip or an LED package including at least one LED chip. The light assembly 21a may consist of a colored LED that emits at least one of red, green and blue light, or a white LED. The colored LED may include at least one of a red LED, a green LED, and a blue LED.

The reflective sheet 22 may be positioned at the front of the substrate 21. The reflective sheet 22 may include a plurality of holes 22a in which the light assembly 21a is positioned. The reflective sheet 22 may reflect light, emitted from the light assembly 21a or reflected from the diffusion plate 23, forward. For example, the reflective sheet 22 may include a metal and/or a metal oxide having a high reflectance such as at least one of aluminum (Al), silver (Ag), gold (Au), and titanium dioxide (TiO2). A supporter 22b may be disposed between the reflective sheet 22 and the diffusion plate 23.

The diffusion plate 23 may be positioned at the front of the reflective sheet 22. The diffusion plate 23 may be positioned between the reflective sheet 22 and the optical sheet 25.

The optical sheet 25 may include at least one sheet. Specifically, the optical sheet 25a, 25b, 25c may include one or more prism sheets and/or one or more diffusion sheets.

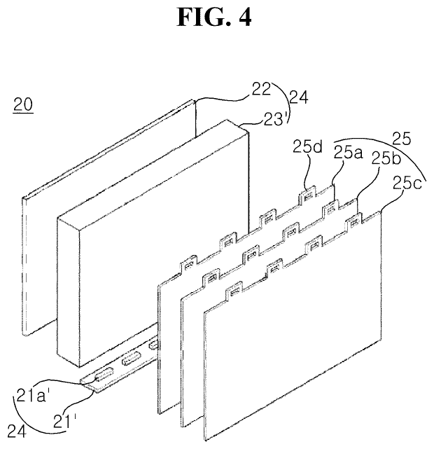

Referring to FIG. 4, the backlight unit 20 may include an optical layer 24 that includes a substrate 21′, at least one light assembly 21a', a reflective sheet 22, and a light guide plate 23′, and an optical sheet 25 that is positioned at the front of the optical layer 24.

The substrate 21′ may be adjacent to a side of the light guide plate 23′ so as to extend along the side. At least one light assembly 21a′ may be mounted on the substrate 21′. Accordingly, most of the light emitted from the light assembly 21a′ may be transmitted into the light guide plate 23′. The light guide plate 23′ may reflect the light incident from the light assembly 21a′ forward.

The reflective sheet 22 may be positioned at the rear of the light guide plate 23′. The reflective sheet 22 may reflect light, emitted from the light assembly 21a′ or reflected from the light guide plate 23′, forward.

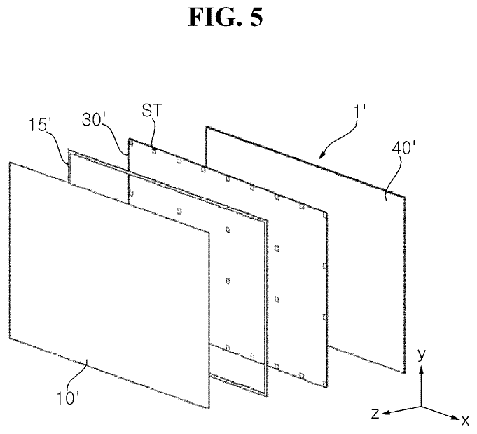

Referring to FIG. 5, unlike the embodiments described above, a display device 1′ may include a display panel 10′, a middle frame 15′, a frame 30′, and a back cover 40′.

The display panel 10′ may form a front surface of the display device 1′, and may display an image to the front. The display panel 10′ may include a plurality of pixels to output an image in accordance with color, brightness, and chroma of each pixel. The display panel 10′ may be divided into an active area in which an image is displayed and a de-active area in which no image is displayed. The display panel 10′ may generate light corresponding to a red, green or blue color in response to a control signal. The display panel 10′ may be referred to as an OLED panel 10′.

The middle frame 15′ may form a side surface of the display device 1′. The middle frame 15′ may be positioned at the rear of the display panel 10′, and may be coupled to the display panel 10′. The middle frame 15′ may have the shape of a generally rectangular ring.

The frame 30′ may be coupled to the rear of the middle frame 15′. A printed circuit board (PCB) on which a plurality of electronic elements are disposed may be coupled to the frame 30′.

The back cover 40′ may be coupled to the rear of the frame 30′. The back cover 40′ may form a rear surface of the display device 1′.

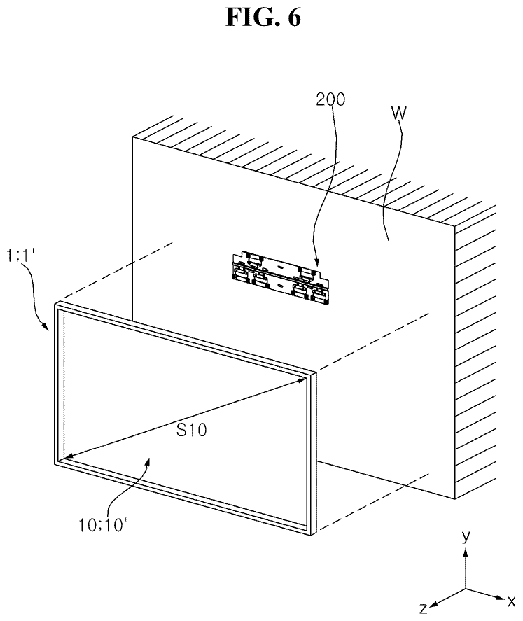

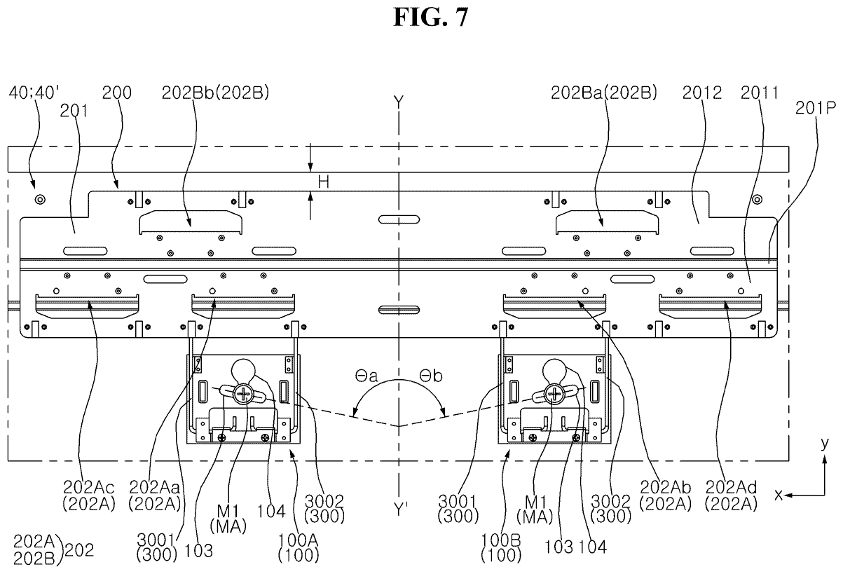

Referring to FIGS. 6 and 7, a bracket 200 may be coupled to a fixed (or stationary) object W. The fixed object W may be a wall or a stud. The stud may include a wood material. The bracket 200 may be referred to as a wall bracket 200 or a stud bracket 200.

The display device (1; 1′) may be positioned in front of the bracket 200. A mount 100 may be coupled to the rear of the back cover (40; 40′) of the display device (1; 1′). A fastening member M may pass through the mount 100 and be fastened to a hole of the back cover (40; 40′). The fastening member M may be a screw. The hole of the back cover (40; 40′) to which the fastening member M is fastened may be a VESA (Video Electronics Standards Association) hole.

A first mount 100A may be positioned to correspond to a first hole of the back cover (40; 40′). A first fastening member MA may couple the first mount 100A to the first hole of the back cover (40; 40′). The first mount 100A may be coupled to the bracket 200.

A second mount 100B may be positioned to correspond to a second hole of the back cover (40; 40′). A second fastening member MB may couple the second mount 100B to the second hole of the back cover (40; 40′). The second mount 100B may be coupled to the bracket 200.

The first and second mounts 100A and 100B may be spaced apart from each other in a longitudinal direction of the bracket 200. The first and second mounts 100A and 100B may be symmetrical in the left-right direction. Specifically, the first and second mounts 100A and 100B may be symmetrical to each other with respect to a vertical line VV′ between the first and second mounts 100A and 100B. The description of any one of the first and second mounts 100A and 100B may be symmetrically applied to the other.

The first and second holes of the back cover (40; 40′) to which the first and second fastening members MA and MB are fastened may be VESA holes. The first and second fastening members MA and MB may be identical to each other. The first and second fastening members MA and MB may be screws.

Accordingly, the display device (1; 1′) may be installed on (or mounted to) the fixed structure W using the mount 100 and the bracket 200. The mount 100, the bracket 200, and a wire 300 to be described later may be components of the display device (1; 1′). The display device (1; 1′) may include a display, a mount 100, a bracket 200, and a wire 300. The mount 100, the bracket 200, and the wire 300 may be collectively referred to as a bracket assembly. The display may include a display panel (10; 10′). The display may include a display panel (10; 10′), a back cover (40; 40′), and components between the display panel (10; 10′) and the back cover (40; 40′).

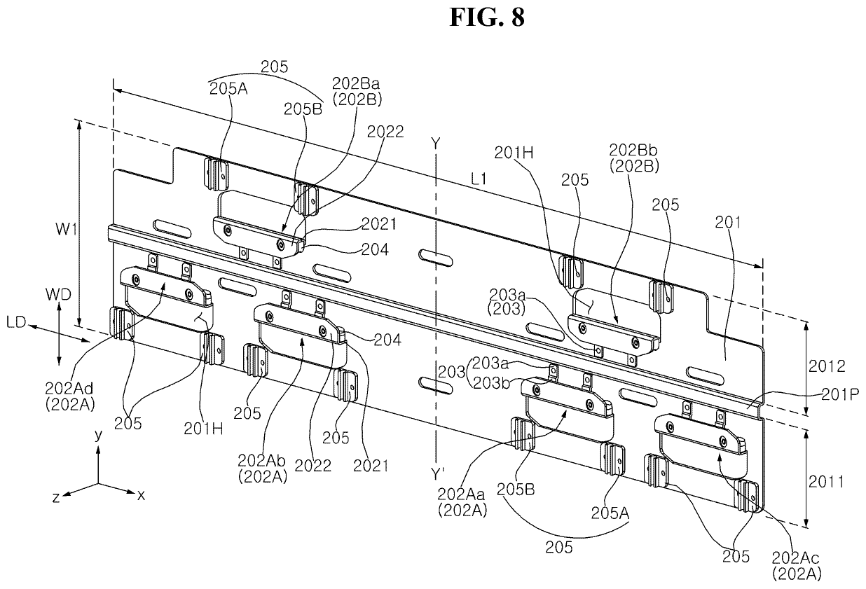

Referring to FIG. 8, the bracket 200 may include a base 201 and a coupling portion 202. The base 201 and the coupling portion 202 may include a metal material.

The base 201 may have a generally elongated plate shape. A length or (longitudinal) direction of the base 201 may be defined in the left-right direction. A length L1 of the base 201 may be greater than a width W1 of the base 201. A pressed portion 201P may be formed on the base 201. The pressed portion 201P may be formed by being pressed forward from a rear surface of the base 201. The pressed portion 201P may extend in the left-right direction. The pressed portion 201P may be formed between a first part 2011 and a second part 2012 of the base 201. The pressed portion 201P may enhance rigidity of the base 201. The first part 2011 may be referred to as a lower portion 2011 of the base 201, and the second part 2012 may be referred to as an upper portion 2012 of the base 201.

The coupling portion 202 may protrude forward from the base 201. A portion of the coupling portion 202 may be bent. The coupling portion 202 may include a protruding portion 2021 and a support portion 2022. The protruding portion 2021 may protrude from a front surface of the base 201, and may intersect the base 201. The support portion 2022 may be bent from the protruding portion 2021, and may face the front surface of the base 201. The support portion 2022 may be bent from the protruding portion 2021 in a width direction (WD) of the base 201. The support portion 2022 may be referred to as a bent portion 2022. The protruding portion 2021 and the support portion 2022 may extend in the length direction (LD) of the base 201, namely, in the left-right direction.

A hole 201H may be formed in the base 201, and may be positioned to correspond to the coupling portion 202. The protruding portion 2021 of the coupling portion 202 may be adjacent to the hole 201H of the base 201. For example, the coupling portion 202 may be formed by cutting and bending a portion of the base 201, and the hole 201H may be formed in the base 201 so as to correspond to the formation of the coupling portion 202.

A plurality of coupling portions 202 may be formed in the base 201. The plurality of coupling portions 202 may be arranged along the length direction of the base 201. The plurality of coupling portions 202 may be formed in the first part 2011 and/or the second part 2012. Coupling portions 202A formed in the first part 2011 may have the same shape. Coupling portions 202B formed in the second part 2012 may have the same shape. The shape of the coupling portion 202B formed in the second part 2012 may be the same as the shape of the coupling portion 202A formed in the first part 2011, rotated 180 degrees about a thickness direction axis (i.e., a z-axis) of the base 201. The coupling portions 202A and 202B may be adjacent to the pressed portion 201P.

A pair of first coupling portions 202Aa and 202Ab may be formed in the first part 2011 of the base 201. The support portions 2022 of the pair of first coupling portions 202Aa and 202Ab may be bent upward from the protruding portions 2021. That is, the support portions 2022 may be bent from the protruding portions 2021 so as to face the pressed portion 201P. In the length direction of the base 201, the pair of first coupling portions 202Aa and 202Ab may be spaced apart from each other by a first distance D1.

A pair of second coupling portions 202Ba and 202Bb may be formed in the second part 2012 of the base 201. The support portions 2022 of the pair of second coupling portions 202Ba and 202Bb may be bent downward from the protruding portions 2021. That is, the support portions 2022 may be bent from the protruding portions 2021 so as to face the pressed portion 201P. In the length direction of the base 201, the pair of second coupling portions 202Ba and 202Bb may be spaced apart from each other by a second distance D2. The second distance D2 may be greater than the first distance D1.

A pair of third coupling portions 202Ac and 202Ad may be formed in the first part 2011 of the base 201. The support portions 2022 of the pair of third coupling portions 202Ac and 202Ad may be bent upward from the protruding portions 2021. That is, the support portions 2022 may be bent from the protruding portions 2021 so as to face the pressed portion 201P. In the length direction of the base 201, the pair of third coupling portions 202Ac and 202Ad may be spaced apart from each other by a third distance D3. The third distance D3 may be greater than the second distance D2. The third coupling portion 202Ac may be disposed between a left side of the base 201 and the first coupling portion 202Aa. The third coupling portion 202Ad may be disposed between a right side of the base 201 and the first coupling portion 202Ab.

An elastic member 203 may be positioned between the support portion 2022 of the coupling portion 202 and the base 201, and may be coupled to the base 201. A fixing portion 203a of the elastic member 203 may be fixed to the front surface of the base 201. A guide portion 203b of the elastic member 203 may be bent from the fixing portion 203a toward the support portion 2022, and may be spaced apart from the support portion 2022. The elastic member 203 may have elasticity. The elastic member 203 may include a metal material. The elastic member 203 may be referred to as a leaf spring 203. A pair of elastic members 203 may be positioned to correspond to each coupling portion 202.

A pad 204 may be positioned between the support portion 2022 of the coupling portion 202 and the base 201, and may be positioned on the protruding portion 2021 of the coupling portion 202. The pad 204 may be positioned between the protruding portion 2021 and the elastic member 203. The pad 204 may be coupled to the base 201 and/or the support portion 2022. The pad 204 may extend in an elongated manner along the protruding portion 2021. The pad 204 may include a material such as plastic, resin, urethane, silicone, or the like. The pad 204 may be an injection-molded part. Each of a plurality of pads 204 may be positioned to correspond to a respective one of the plurality of coupling portions 202.

A holder 205 may be coupled to the front surface of the base 201. The holder 205 may be opposite the coupling portion 202. The support portion 2022 of the coupling portion 202 may be bent from the protruding portion 2021 in a first direction, and the holder 205 may be spaced apart from the coupling portion 202 in a second direction opposite to the first direction. The holder 205 may be positioned closer to an edge of the base 201 than the coupling portion 202. A pair of holders 205A and 205B may be positioned to correspond to each coupling portion 202. The pair of holders 205A and 205B may be spaced apart from each other in a length direction of the coupling portion 202. A distance D5 between the pair of holders 205A and 205B may be greater than a length L2 of the coupling portion 202. The holder 205 may include a material such as plastic, resin, urethane, silicone, or the like. The holder 205 may be an injection-molded part.

For example, the bracket 200 described above and below may be left-right symmetric with respect to a vertical line YY′ passing through the center of the bracket 200.

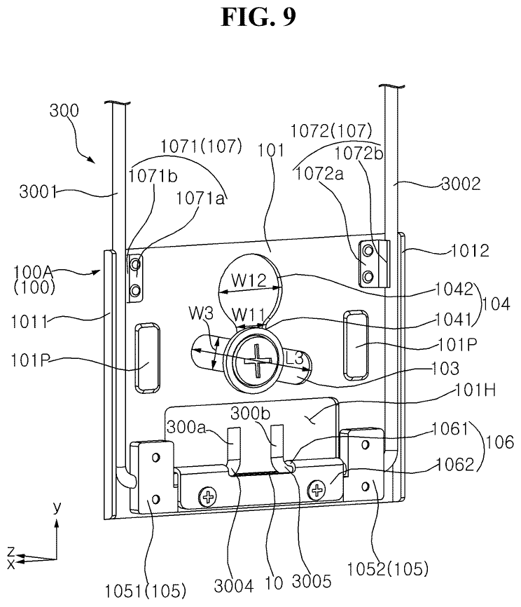

Referring to FIG. 9 along with FIG. 7, the mount 100 may include a body 101 and a slot 103. The body 101 may include a metal material.

The body 101 may have the shape of a generally rectangular plate. A front surface of the body 101 may face a rear surface of the back cover (40; 40′) of the display device (1; 1′). The front surface of the body 101 may be parallel to the rear surface of the back cover (40; 40′). A pressed portion 101P may be formed on the body 101. The pressed portion 101P may be formed by being pressed rearward from the front surface of the body 101. The pressed portion 101P may enhance rigidity of the body 101.

The slot 103 may be formed in the body 101. The slot 103 may be formed at or near a central portion of the body 101. The slot 103 may be an obliquely elongated hole. Referring to FIG. 7, the slot 103 of the first mount 100A may be inclined counterclockwise by a first angle θa from the vertical line VV′ between the first and second mounts 100A and 100B. Referring to FIG. 7, the slot 103 of the second mount 100B may be inclined counterclockwise by a second angle θb from the vertical line VV′ between the first and second mounts 100A and 100B. The second angle θb may be equal to the first angle θa. The first angle θa may be an acute angle.

A guide hole 104 may be formed from a portion of the slot 103 into the inside of the body 101. The guide hole 104 may be positioned at an intermediate portion between one end and the other end of the slot 103. The slot 103 may be positioned under the guide hole 104.

For example, the guide hole 104 may include a first hole 1041 and a second hole 1042 (see FIG. 9). The first hole 1041 may be formed from the slot 103 into the inside of the body 101. A width W11 of the first hole 1041 may correspond to a width W3 of the slot 103. The second hole 1042 may be formed from the first hole 1041 into the inside of the body 101. The second hole 1042 may have the shape of a circular hole. A width W12 (i.e., a diameter) of the second hole 1042 may be greater than the width W3 of the slot 103. The width W12 (or diameter) of the second hole 1042 may be less than a length L3 of the slot 103.

As another example, a guide hole 104′ may be formed from the slot 103 into the inside of the body 101. The guide hole 104′ may be a semi-circular notch.

A holder 105 may be coupled to a rear surface of the body 101. The holder 105 may be adjacent to a lower side of the body 101. A first holder 1051 may be adjacent to a left side of the body 101. A second holder 1052 may be adjacent to a right side of the body 101.

A coupling portion 106 may protrude rearward from the body 101, and may be positioned between the first holder 1051 and the second holder 105. A portion of the body 101 may be bent. The coupling portion 106 may include a protruding portion 1061 and a support portion 1062. The protruding portion 1061 may protrude from the rear surface of the body 101, and may intersect the body 101. The support portion 1062 may be bent downward from the protruding portion 1061, and may face the rear surface of the body 101. The support portion 1062 may be referred to as a bent portion 1062. The protruding portion 1061 and the support portion 1062 may extend in an elongated manner along the lower side of the body 101. A through-hole 1063 may be formed in the protruding portion 1061.

A hole 101H may be formed in the body 101, and may be positioned to correspond to the coupling portion 106. The protruding portion 1061 of the coupling portion 106 may be adjacent to the hole 101H of the body 101. For example, the coupling portion 106 may be formed by cutting and bending a portion of the body 101, and the hole 101H may be formed in the body 101 so as to correspond to the formation of the coupling portion 106.

A guide 107 may be coupled to the rear surface of the body 101. The guide 107 may be adjacent to an upper side of the body 101. The guide 107 may include a metal material. The guide 107 may include a first guide 1071 adjacent to the left side of the body 101, and a second guide 1072 adjacent to the right side of the body 101.

A fixing portion 1071a of the first guide 1071 may be coupled to the rear surface of the body 101. A support portion 1071b of the first guide 1071 may be bent rearward from the fixing portion 1071a. A first rib 1011 may be bent rearward from the left side of the body 101, and may extend vertically. The first rib 1011 may face the support portion 1071b, and may be spaced apart from the support portion 1071b. A distance between the first rib 1011 and the support portion 1071b may be less than a diameter of the wire 300 described below. The first guide 1071 may have elasticity. The first guide 1071 may be referred to as a leaf spring 1071.

A fixing portion 1072a of the second guide 1072 may be coupled to the rear surface of the body 101. A support portion 1072b of the second guide 1072 may be bent rearward from the fixing portion 1072a. A second rib 1012 may be bent rearward from the right side of the body 101, and may extend vertically. The second rib 1012 may face the support portion 1072b, and may be spaced apart from the support portion 1072b. A distance between the second rib 1012 and the support portion 1072b may be less than the diameter of the wire 300 described below. The second guide 1072 may have elasticity. The second guide 1072 may be referred to as a leaf spring 1072.

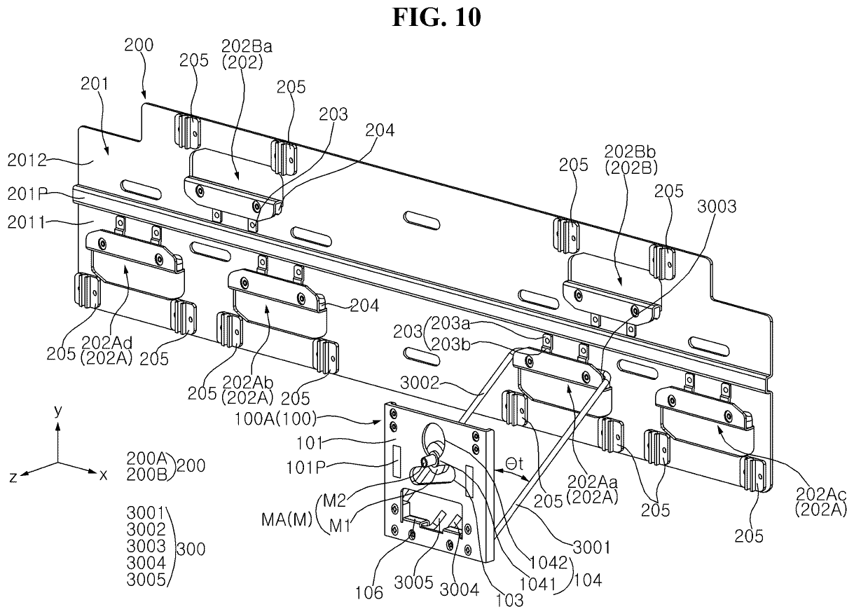

The wire 300 may have a generally square loop shape. The wire 300 may form an open loop, in which a first end 300a and a second end 300b of the wire 300 may be spaced apart from each other. Alternatively, the wire 300 may form a closed loop. The wire 300 may include a metal material. The wire 300 may be positioned at the rear of the mount 100. The wire 300 may include a first part 3001, a second part 3002, a third part 3003 (see FIG. 10), a fourth part 3004, and a fifth part 3005.

The first part 3001 may form a left side of the wire 300. The first part 3001 may be positioned between the first rib 1011 and the first guide 1071, and may extend in an elongated manner. The first part 3001 may form a long side of the wire 300.

The second part 3002 may form a right side of the wire 300. The second part 3002 may be positioned between the second rib 1012 and the second guide 1072, and may extend in an elongated manner. The second part 3002 may form a long side of the wire 300.

The third part 3003 may form an upper side of the wire 300. The third part 3003 may connect the first part 3001 and the second part 3002. The third part 3003 may form a short side of the wire 300.

The fourth part 3004 may be bent from a lower end of the first part 3001, and may form a portion of the lower side of the wire 300. The fourth part 3004 may pass through the first holder 1051 and be inserted into the coupling portion 106. A portion of the fourth part 3004 may be bent so as to pass through the through-hole 1063 of the coupling portion 106, and may form the first end 300a of the wire 300.

The fifth part 3005 may be bent from a lower end of the second part 3002, and may form a portion of the lower side of the wire 300. The fifth part 3005 may pass through the second holder 1052 and be inserted into the coupling portion 106. A portion of the fifth part 3005 may be bent so as to pass through the through-hole 1063 of the coupling portion 106, and may form the second end 300b of the wire 300.

Accordingly, the wire 300 may be coupled to the mount 100. The fourth and fifth parts 3004 and 3005 of the wire 300 may be rotatably coupled to the holder 105. The wire 300 coupled to the mount 100 may be rotatable about a left-right axis (i.e., an x-axis).

Referring to FIG. 10 along with FIG. 7, the fastening member M may include a head M1 and a body M2.

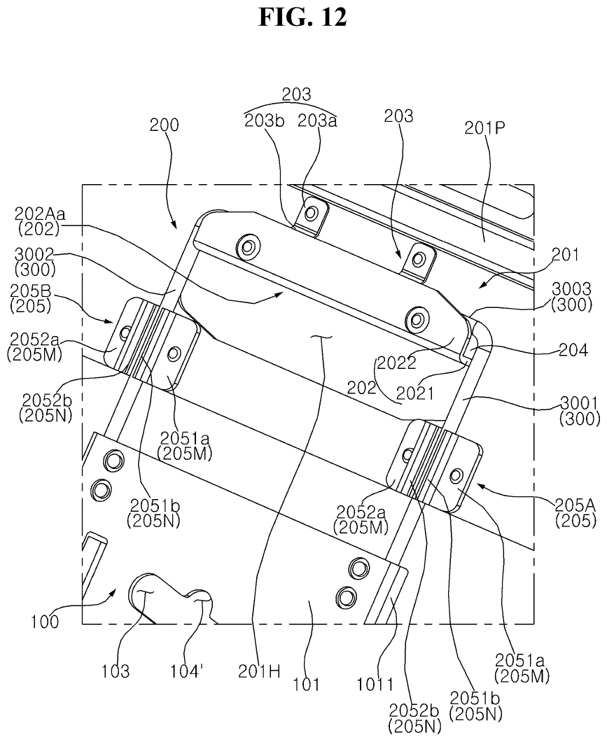

The head M1 may be a head of a screw. The head M1 may be positioned at the rear of the body 101 of the mount 100. A diameter of the head M1 may be greater than the width W3 (see FIG. 9) of the slot 103 of the body 101. The head M1 may be engaged with the rear surface of the body 101. Meanwhile, the diameter of the head M1 may be equal to or less than the diameter of the first hole 1041 of the guide hole 104. Alternatively, the diameter of the head M1 may be greater than a diameter of the guide hole 104′ (see FIG. 12).

The body M2 may be a body of the screw, and a thread may be formed on an outer surface of the body M2. A diameter of the body M2 may be less than the diameter of the head M1, and may pass through the slot 103 of the body 101. The body M2 may be engaged in the slot 103 of the body 101. The body 101 may be fastened to the hole of the back cover (40; 40′) of the display device (1; 1′). The hole of the back cover (40; 40′) to which the body 101 is fastened may be a VESA hole.

The first fastening member MA may pass through the first mount 100A and be fastened to the first hole of the back cover (40; 40′). The first fastening member MA may be engaged with a rear surface of the first mount 100A, and may be positioned in the slot 103 of the first mount 100A.

The second fastening member MB may pass through the second mount 100B and be fastened to the second hole of the back cover (40; 40′). The second fastening member MB may be engaged with a rear surface of the second mount 100B, and may be positioned in the slot 103 of the second mount 100B.

Accordingly, the display device (1; 1′) may be coupled to the first and second mounts 100A and 100B via the first and second fastening members MA and MB. In addition, by adjusting the position of the first and second fastening members MA and MB on the slots 103 of the first and second mounts 100A and 100B, it is possible to adjust the left-right tilt of the display device (1; 1′).

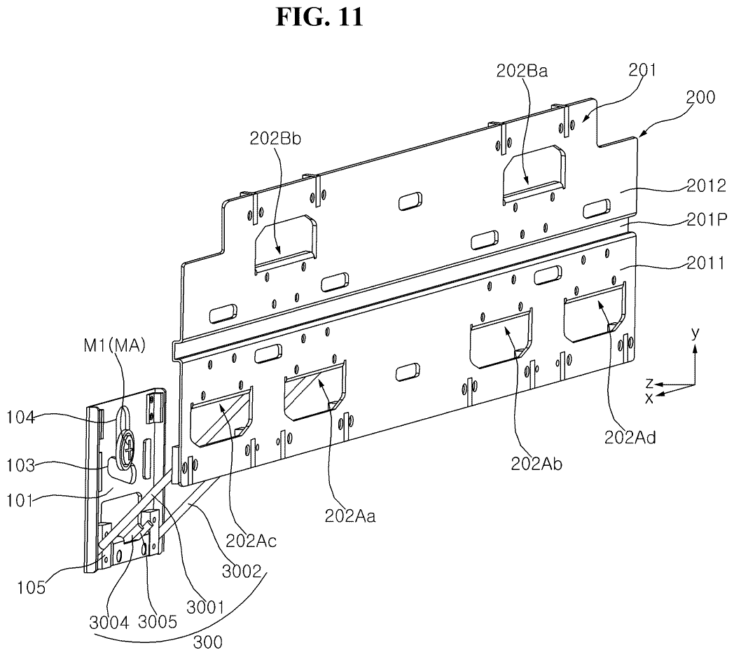

Referring to FIGS. 10 and 11, the wire 300 may be positioned between the mount 100 and the bracket 200. One side of the wire 300 may be coupled to the mount 100, and another side of the wire 300 may be coupled to the coupling portion 202 of the bracket 200. For example, in a state where the wire 300 is tilted from the mount 100 toward the bracket 200 (see an angle θt of FIG. 10), the third part 3003 of the wire 300 may be engaged with the coupling portion 202.

Specifically, the third part 3003 of the wire 300 may pass through a gap between the guide portion 203b of the elastic member 203 and the support portion 2022 of the coupling portion 202. The third part 3003 of the wire 300 having passed through the gap may be positioned on the pad 204 and be engaged with the coupling portion 202.

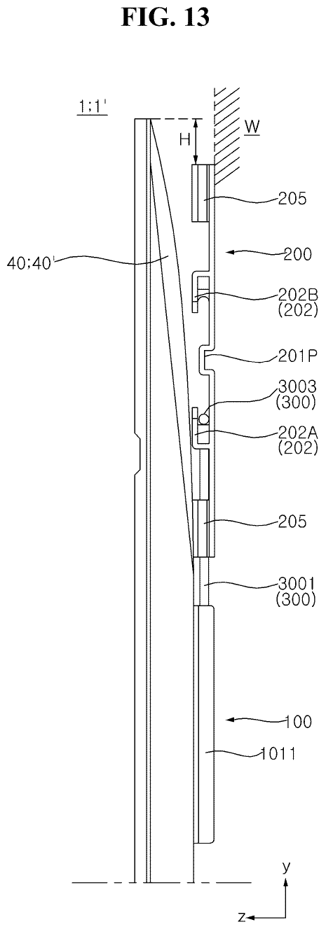

Referring to FIGS. 12 and 13, a base 205M of the holder 205 may be fixed to the front surface of the base 201. Fixing portions 205N of the holder 205 may protrude forward from the base 205M, and may be spaced apart from each other. A distance between the fixing portions 205N may be less than the diameter of the wire 300. The holder 205 may have elasticity. The holder 205 may include a first holder 2051 and a second holder 2052.

A base 2051a of the first holder 2051 may be fixed to the front surface of the base 201. The base 2051a may form a portion of the base 205M of the holder 205. A fixing portion 2051b of the first holder 2051 may protrude forward from the base 2051a. The fixing portion 2051b may be one of the fixing portions 205N of the holder 205.

A base 2052a of the second holder 2052 may be fixed to the front surface of the base 201. The base 2052a may form a portion of the base 205M of the holder 205. A fixing portion 2052b of the second holder 2052 may protrude forward from the base 2052a. The fixing portion 2052b may be one of the fixing portions 205N of the holder 205.

A user may move the mount 100 and the wire 300 of FIG. 10 toward the bracket 200. In this case, the wire 300 may be rotated counterclockwise with respect to the bracket 200, and the mount 100 may be rotated clockwise with respect to the wire 300. Accordingly, the wire 300 may be partially overlapped with (or placed over) the bracket 200, and the mount 100 may be partially overlapped with the wire 300.

At this time, the first part 3001 of the wire 300 may be inserted between the fixing portions 205N of the holder 205A, and the second part 3002 of the wire 300 may be inserted between the fixing portions 205N of the holder 205B. The fixing portions 205N may be slightly spread apart by the wire 300, and the holder 205 may hold the wire 300 by an elastic restoring force. That is, unless an external force of a predetermined magnitude or greater is applied, the wire 300 may remain partially overlapped with the bracket 200. In this manner, the holder 205 may minimize a tilt of the wire 300 in the front-rear direction. Also, the holder 205 may prevent a tilt of the wire 300 in the left-right direction.

In addition, the first part 3001 of the wire 300 may be inserted between the first rib 1011 of the body 101 and the first guide 1071, and the second part 3002 of the wire 300 may be inserted between the second rib 1012 of the body 101 and the second guide 1072 (see FIG. 9). The guides 1071 and 1072 may be slightly spread apart from the ribs 1011 and 1012 by the wire 300, and the guides 1071 and 1072 may hold the 300 by an elastic restoring force. That is, unless an external force of a predetermined magnitude or greater is applied, the mount 100 may remain partially overlapped with the wire 300. In this manner, the guide 107 may minimize a tilt of the mount 100. Also, the guide 107 may prevent a tilt of the mount 100 in the left-right direction.

Accordingly, the mount 100 may be coupled to the bracket 200 via the wire 300. The bracket 200 and the mount 100, which is positioned below the bracket 200, may be located on any one plane (i.e., an xy-plane), and the wire 300 may connect the bracket 200 and the mount 100.

For example, the first mount 100A may be coupled to the first coupling portion 202Aa via the wire 300. Alternatively, the first mount 100A may be coupled to the third coupling portion 202Ac via the wire 300. Alternatively, the first mount 100A may be coupled to the second coupling portion 202Ba via the wire 300.

Similarly, the second mount 100B (see FIG. 7) may be coupled to the first coupling portion 202Ab via the wire 300. Alternatively, the second mount 100B may be coupled to the third coupling portion 202Ad via the wire 300. Alternatively, the second mount 100B may be coupled to the second coupling portion 202Bb via the wire 300.

Referring to FIG. 13 along with FIG. 7, the back cover (40; 40′) of the display device (1; 1′) may be coupled to the first and second mounts 100A and 100B via the first and second fastening members MA and MB. The first and second mounts 100A and 100B may be coupled to the bracket 200 via the wires 300.

A front surface of the mount 100 may be positioned on the rear surface of the back cover (40; 40′). The back cover (40; 40′) may be disposed close to the fixed object W on which the bracket 200 is installed.

A front end of the bracket 200 may be located on the same plane as the front surface of the mount 100. The support portion 2022 of the coupling portion 206 may form the front end of the bracket 200. The holder 205 may form the front end of the bracket 200. The front end of the bracket 200 may be adjacent to the rear surface of the back cover (40; 40′). For example, a portion of the back cover (40; 40′) positioned above the mount 100 may be curved, and a distance between the back cover (40; 40′) and the bracket 200 may increase with increasing distance from the mount 100.

The bracket 200 may be adjacent to an upper side of the back cover (40; 40′). As an upper end of the bracket 200 is disposed closer to the upper side of the back cover (40; 40′), a length of the wire 300 connecting the bracket 200 and the mount 100 may increase, thereby reducing the occurrence of the display device (1; 1′) from tilting or leaning forward. However, in order to make the bracket 200 not visible when viewed from the front of the display device (1; 1′), the upper end of the bracket 200 may be positioned at the same height as or below the upper side of the back cover (40; 40′) (see a height difference H of FIG. 13).

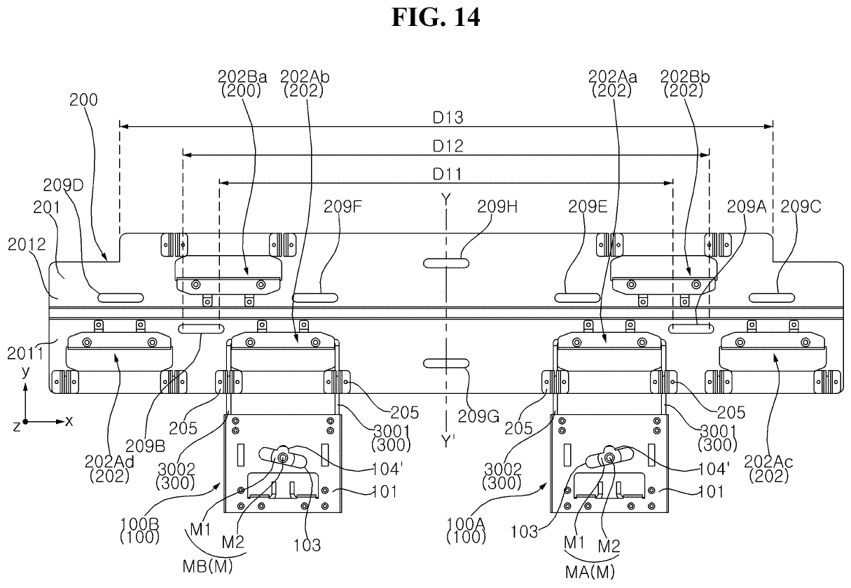

Referring to FIGS. 14 to 16, a fixing hole 209 may be formed in the base 201 of the bracket 200. The fixing hole 209 may be a hole elongated in the length direction of the base 201. A plurality of fixing holes 209 may have the same length. Alternatively, the plurality of fixing holes 209 may have different lengths. The plurality of fixing holes 209 may be formed in pairs at several positions of the base 201.

A pair of first fixing holes 209A and 209B may be formed in the first part 2011 of the base 201, and may be spaced apart from each other in the length direction of the base 201. The first fixing hole 209A may be positioned between the first coupling portion 202Aa and the third coupling portion 202Ac. The first fixing hole 209B may be positioned between the first coupling portion 202Ab and the third coupling portion 202Ad.

A pair of second fixing holes 209C and 209D may be formed in the second part 2012 of the base 201, and may be spaced apart from each other in the length direction of the base 201. The second fixing hole 209C may be positioned closer to the left side of the base 201 than the first fixing hole 209A. The second fixing hole 209D may be positioned closer to the right side of the base 201 than the first fixing hole 209B.

A pair of third fixing holes 209E and 209F may be formed in the second part 2012 of the base 201, and may be spaced apart from each other in the length direction of the base 201. The pair of third fixing holes 209E and 209F may be positioned between the pair of second coupling portions 202Ba and 202Bb.

A pair of fourth fixing holes 209G and 209H may be formed in the first part 2011 and the second part 2012 of the base 201, and may be spaced apart from each other in the width direction of the base 201. The pair of fourth fixing holes 209G and 209H may be located on a vertical line YY′ passing through the center of the bracket 200.

For example, a pair of fastening members such as nails or screws may be spaced apart from each other by a first distance D11, and may pass through the pair of first fixing holes 209A and 209B and be fastened to the fixed object W (see FIG. 6). Accordingly, the bracket 200 may be secured to the fixed object W, such as a wall or a stud. For example, the first distance D11 may be 400 mm.

For example, a pair of fastening members such as nails or screws may be spaced apart from each other by a second distance D12, and may pass through the pair of first fixing holes 209A and 209B and be fastened to the fixed object W (see FIG. 6). Accordingly, the bracket 200 may be secured to the fixed object W, such as a wall or a stud. For example, the second distance D12 may be 455 mm.

For example, a pair of fastening members such as nails or screws may be spaced apart from each other by a third distance D13, and may pass through the pair of second fixing holes 209C and 209D and be fastened to the fixed object W (see FIG. 6). Accordingly, the bracket 200 may be secured to the fixed object W, such as a wall or a stud. For example, the third distance D13 may be 600 mm.

Thus, the bracket 200 may be secured to the fixed object W, such as a wall or a stud, at various positions.

Referring to FIG. 14, the first mount 100A may be coupled to the first coupling portion 202Aa via the wire 300, and the second mount 100B may be coupled to the first coupling portion 202Ab via the wire 300B. The back cover (40; 40′) (see FIGS. 6 and 7) may be coupled to the first and second mounts 100A and 100B via the first and second fastening members MA and MB. In this case, a size S10 of the display panel (10; 10′) (see FIG. 6) of the display device (1; 1′) may be a first size. For example, a distance between the first and second fastening members MA and MB may be 300 mm.

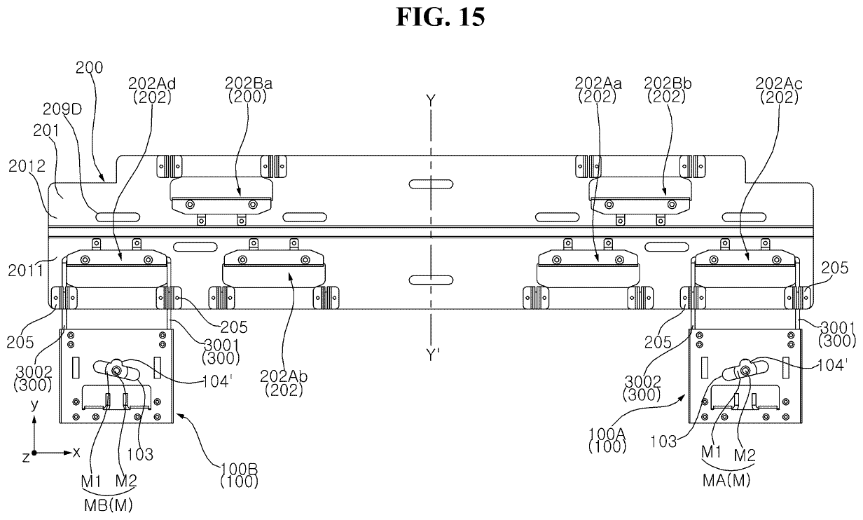

Referring to FIG. 15, the first mount 100A may be coupled to the third coupling portion 202Ac via the wire 300, and the second mount 100B may be coupled to the third coupling portion 202Ad via the wire 300. The back cover (40; 40′) (see FIGS. 6 and 7) of the display device (1; 1′) may be coupled to the first and second mounts 100A and 100B via the first and second fastening members MA and MB. In this case, a size S10 of the display panel (10; 10′) (see FIG. 6) of the display device (1; 1′) may be a second size greater than the first size. For example, a distance between the first and second fastening members MA and MB may be 600 mm.

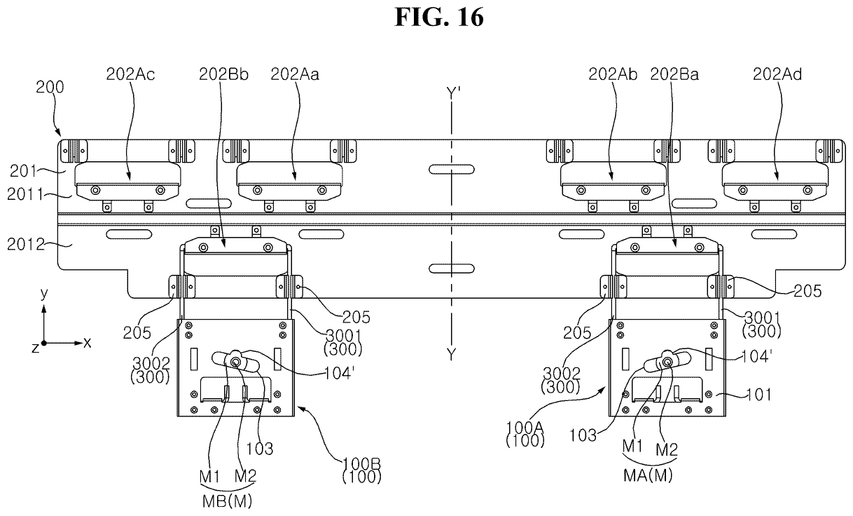

Referring to FIG. 16, the bracket 200 may be identical to the bracket 200 of FIGS. 14 and 15 rotated 180 degrees about a thickness direction axis (i.e., a z-axis) of the base 201. The first mount 100A may be coupled to the second coupling portion 202Ba via the wire 300, and the second mount 100B may be coupled to the second coupling portion 202Bb via the wire 300. The back cover (40; 40′) (see FIGS. 6 and 7) of the display device (1; 1′) may be coupled to the first and second mounts 100A and 100B via the first and second fastening members MA and MB. In this case, the display panel (10; 10′) (see FIG. 6) of the display device (1; 1′) may have a size S10 greater than the first size and less than the second size. For example, a distance between the first and second fastening members MA and MB may be 400 mm.

Accordingly, the bracket 200 may be used to install the display device (1; 1′) in three sizes on the fixed object W. In addition, by forming the first and third coupling portions 202Aa, 202Ab, 202Ac, and 202Ad on the first part 2011 of the base 201 while forming the second coupling portions 202Ba and 202Bb on the second part 2012 of the base 201, the coupling portions 202 may be efficiently positioned at the base 201. In contrast, when the second coupling portions 202Ba and 202Bb are arranged side by side with the first and third coupling portions 202Aa, 202Ab, 202Ac, and 202Ad, it requires an increase in the length of the bracket 200.

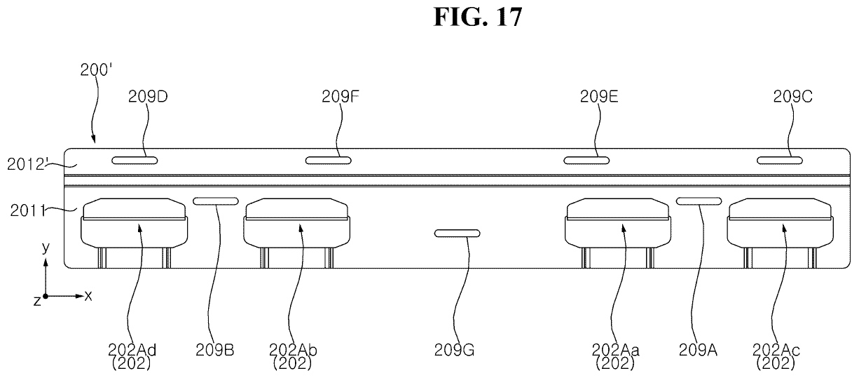

Referring to FIG. 17, unlike the embodiment described above, a bracket 200′′ may include first coupling portions 202Aa and 202Ab and third coupling portions 202Ac and 202Ad, and may not include second coupling portions 202Ba, 202Bb (see FIGS. 14 to 16).

The display device (1; 1′) (see FIG. 6) having a display panel of the first size may be coupled to the first coupling portions 202Aa and 202Ab via the first and second mounts 100A and 100B and the wires 300 described above with reference to FIG. 14.

The display device (1; 1′) (see FIG. 6) having a display panel with the second size may be coupled to the third coupling portions 202Ac and 202Ad via the first and second mounts 100A and 100B and the wires 300 described above with reference to FIG. 15.

Accordingly, the bracket 200′′ may be used to install the display device (1; 1′) in two sizes on the fixed object W.

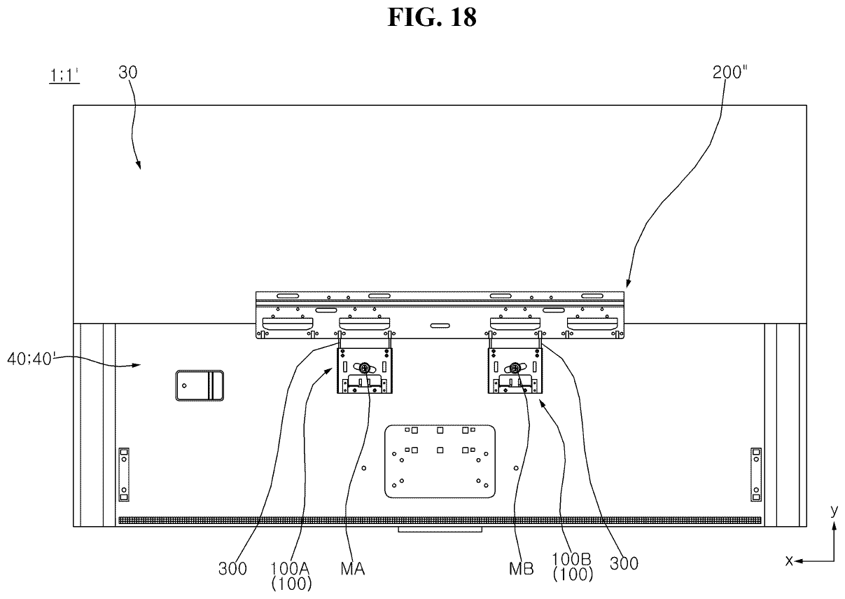

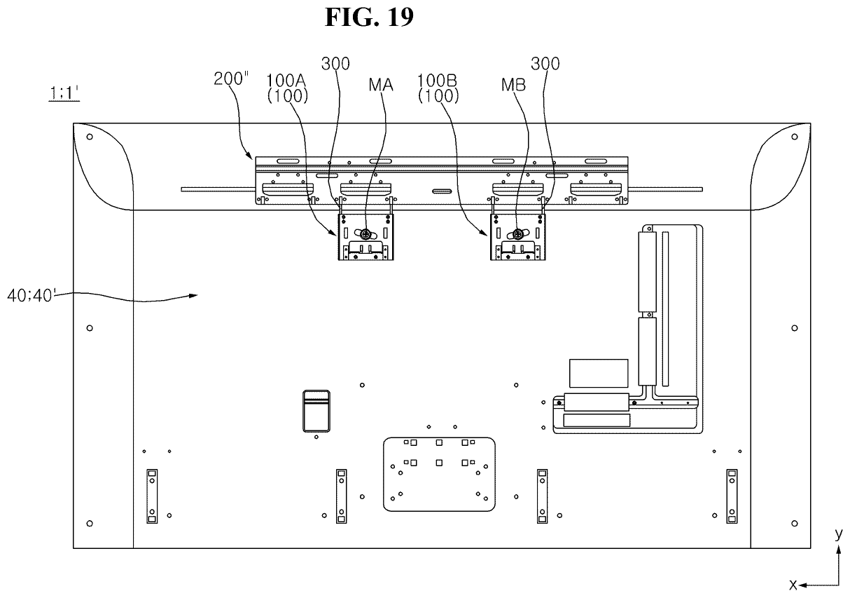

Referring to FIGS. 18 and 19, the size of the back cover (40; 40′) of the display device (1; 1′) may vary.

Referring to FIG. 18, the back cover (40; 40′) may form a portion of the rear surface of the display device (1; 1′). The frame 30 may form a remaining portion of the rear surface of the display device (1; 1′). The back cover (40; 40′) may cover the rear of a lower portion of the frame 30, and the rear of an upper portion of the frame 30 may be exposed. Holes Hv disposed at vertices of a rectangular may be formed in the back cover (40; 40′). The holes Hv may be VESA holes. The first and second fastening members MA and MB may pass through the first and second mounts 100A and 100B and be fastened to, among the holes Hv, holes located at a relatively upper side. Heads of the first and second fastening members MA and MB may be engaged with rear surfaces of the first and second mounts 100A and 100B, and the first and second mounts 100A and 100B may be coupled to the bracket 200′′ via the wires 300.

Referring to FIG. 19, the back cover (40; 40′) may form the entire rear surface of the display (1; 1′). Holes Hv disposed at vertices of a rectangular may be formed in the back cover (40; 40′). The holes Hv may be VESA holes. The first and second fastening members MA and MB may pass through the first and second mounts 100A and 100B and be fastened to, among the holes Hv, holes located at a relatively upper side. Heads of the first and second fastening members MA and MB may be engaged with rear surfaces of the first and second mounts 100A and 100B, and the first and second mounts 100A and 100B may be coupled to the bracket 200′′ via the wires 300.

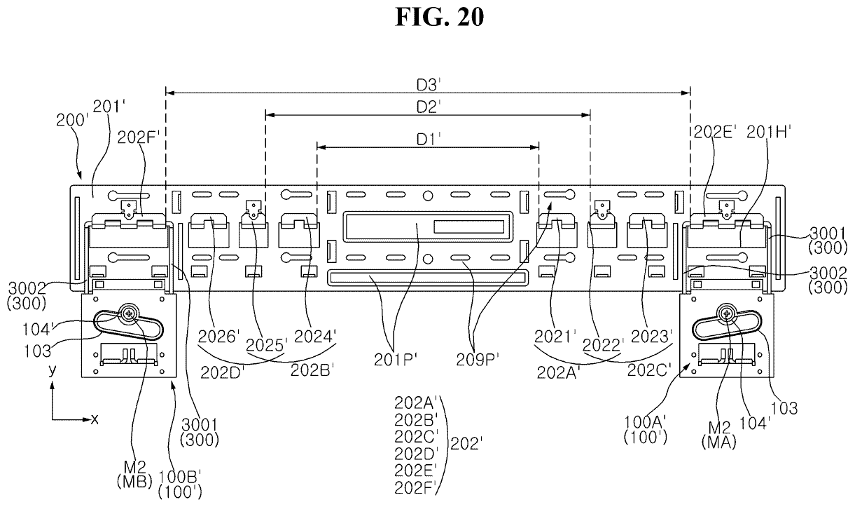

Referring to FIG. 20, unlike the embodiments described above, a bracket 200′ may include a base 201′ and a coupling portion 202′. The base 201′ and the coupling portion 202′ may include a metal material.

The base 201′ may have a generally elongated plate shape. A length (or longitudinal) direction of the base 201′ may be defined in the left-right direction. A length of the base 201′ may be greater than a width of the base 201′. A pressed portion 201P′ may be formed on the base 201′. A plurality of fixing holes 209′ may be formed in the base 201′. Fastening members such as nails or screws may pass through the fixing holes 209′ and be fastened to the fixed object W, such as a wall or a stud, thereby fixing the base 201′ to the wall or stud.

The coupling portion 202′ may protrude forward from the base 201′, and a portion of the coupling portion 202′ may be bent upward. The coupling portion 202′ may include a protruding portion protruding forward from the base 201′, and a bent portion bent upward from the protruding portion.

A hole 201H′ may be formed in the base 201′, and may be positioned to correspond to the coupling portion 202′. For example, the coupling portion 202′ may be formed by cutting and bending a portion of the base 201′, and the hole 201H′ may be formed in the base 201′ so as to correspond to the formation of the coupling portion 202′.

A plurality of coupling portions 202′ may be formed in the base 201′. The plurality of coupling portions 202′ may be arranged along the length direction of the base 201′.

A pair of first coupling portions 202A′ and 202B′ may be formed in the base 201′, and may be spaced apart from each other by a first distance D1′. The first coupling portion 202A′ may include a first part 2021′ and a second part 2022′ that are spaced apart from each other. The first coupling portion 202B′ may include a first part 2024′ and a second part 2025′ that are spaced apart from each other.

A pair of second coupling portions 202C′ and 202D′ may be formed in the base 201′, and may be spaced apart from each other by a second distance D2′. The second distance D2′ may be greater than the first distance D1′. The second coupling portion 202C′ may include a second part 2022′ and a third part 2023′ that are spaced apart from each other. The second coupling portion 202D′ may include a second part 2025′ and a third part 2026′ that are spaced apart from each other.

That is, the first coupling portion 202A′ and the second coupling portion 202C′ may share the second part 2022′. In addition, the first coupling portion 202B′ and the second coupling portion 202D′ may share the second part 2025′.

A pair of third coupling portions 202E′ and 202F′ may be formed in the base 201′, and may be spaced apart from each other by a third distance D3′. The third distance D3′ may be greater than the second distance D2′. A length of each of the pair of third coupling portions 202E′ and 202F′ may correspond to a length of each of the pair of first coupling portions 202A′ and 202B′ or a length of each of the pair of second coupling portions 202C′ and 202D'.

The bracket 200′ may be left-right symmetric with respect to a vertical line passing through the center of the bracket 200′.

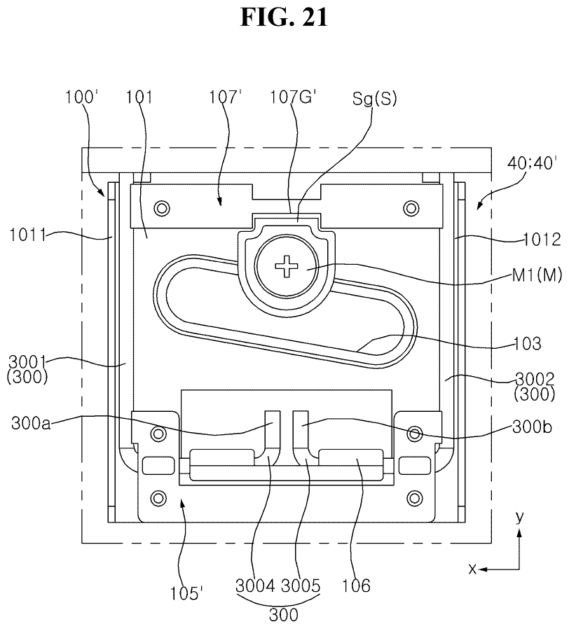

Referring to FIG. 21, a mount 100′ may include a guide 107′ instead of the guide 107 (see FIG. 9) of the mount 100. The guide 107′ may be referred to as a stopper 107′ or a wire stopper 107′.

The guide 107′ may be coupled to a rear surface of a body 101. The guide 107′ may be adjacent to an upper side of the body 101. The guide 107′ may be elongated horizontally. A left side of the guide 107′ may be adjacent to a first rib 1011, and a right side of the guide 107′ may be adjacent to a second rib 1012. A distance between the first rib 1011 and the left side of the guide 107′ may be less than a diameter of a wire 300. A distance between the second rib 1012 and the right side of the guide 107′ may be less than the diameter of the wire 300. The guide 107′ may have elasticity.

A first part 3001 of the wire 300 may form a left side of the wire 300. The first part 3001 may be inserted and fixed between the first rib 1011 and the left side of the guide 107′.

A second part 3002 of the wire 300 may form a right side of the wire 300. The second part 3002 may be inserted and fixed between the second rib 1012 and the right side of the guide 107′.

A third part 3003 of the wire 300 may form an upper side of the wire 300. The third part 3003 may connect the first part 3001 and the second part 3002. The third part 3003 may be positioned on the coupling portion 202′ of the bracket 200′ (see FIG. 20), and may be engaged with the coupling portion 202′.

A fourth part 3004 of the wire 300 may be bent from a lower end of the first part 3001, and may form a portion of the lower side of the wire 300. The fourth part 3004 may pass through a holder 105′ and be inserted into a coupling portion 106. The fourth part 3004 may form a first end 300a of the wire 300.

A fifth part 3005 of the wire 300 may be bent from a lower end of the second part 3002, and may form a portion of the lower side of the wire 300. The fifth part 3005 may pass through the holder 105′ and be inserted into the coupling portion 106. The fifth part 3005 may form a second end 300b of the wire 300.

Accordingly, the wire 300 may be coupled to the mount 100′. The fourth and fifth parts 3004 and 3005 of the wire 300 may be rotatably coupled to the holder 105′. The wire 300 coupled to the mount 100′ may be rotatable about a left-right axis (i.e., an x-axis).

A fastening member M may include a head M1 and a body M2. The head M1 may be a head of a screw. The head M1 may be positioned at the rear of the body 101 of the mount 100′. The head M1 may be engaged with the rear surface of the body 101. The body M2 may be a body of the screw, and may pass through a slot 103 of the body 101. The body 101 may be fastened to a hole (e.g., a VESA hole) of the back cover (40; 40′) of the display device (1; 1′).

A spacer S may be disposed between the rear surface of the body 101 and the head M1. The spacer S may be fixed to the head M1. A boundary of the spacer S may be located outward of a boundary of the head M1. A portion Sg of the spacer S may have an angular shape. The portion Sg may be referred to as a protruding portion Sg.

A guide groove 107G′ may be formed on a lower side of the guide 107′. The guide groove 107G′ may be formed at a central portion of the lower side of the guide 107′. The guide groove 107G′ may be an angular groove. For example, the guide groove 107G′ may be a rectangular groove. The protruding portion Sg of the spacer S may have a shape corresponding to the shape of the guide groove 107G′.

Accordingly, the spacer S and the guide 107′ may guide the coupling of the fastening member M and the mount 100′. Specifically, in a state where the protruding portion Sg of the spacer S is positioned in the guide groove 107G', the fastening member M may be fixed to the back cover (40; 40′), thereby setting the initial position of the fastening member M and the mount 100′.

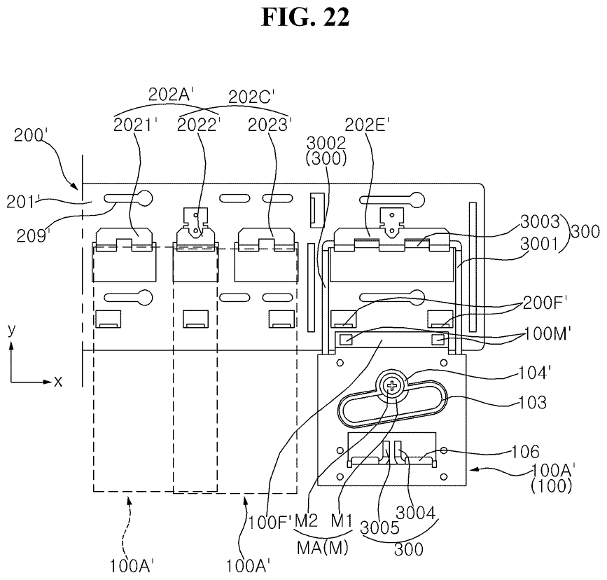

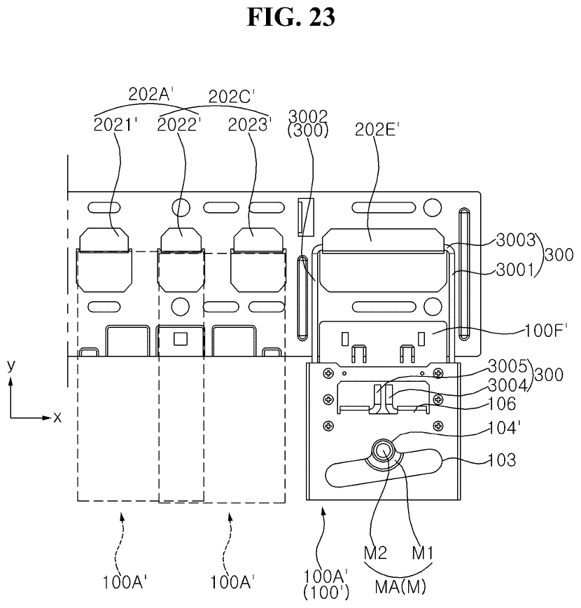

Referring to FIGS. 22 and 23, the mount 100′ may include a guide hole 104′ formed from a portion of the slot 103 into the inside of the body 101. The fastening member M may pass through the guide hole 104′ and then move to the slot 103.

Referring to an example illustrated in FIG. 22, the coupling portion 106 to which the fourth and fifth parts 3004 and 3005 of the wire 300 are rotatably coupled may be positioned below the slot 103.

Referring to an example illustrated in FIG. 23, the coupling portion 106 to which the fourth and fifth parts 3004 and 3005 of the wire 300 are rotatably coupled may be positioned above the slot 103.

When a user moves the mount 100′ and the wire 300 toward the bracket 200′, the wire 300 may be partially overlapped with (or placed over) the bracket 200′, and the mount 100′ may be partially overlapped with the wire 300.

A fixing portion 100F′ may be coupled to the mount 100′ adjacent to an upper side of the mount 100′. The fixing portion 100F′ may overlap a portion of the bracket 200′. A portion 200F′ of the bracket 200′ may contact an upper side of the fixing portion 100F′ or pass through the fixing portion 100F′, thereby restricting the upward movement of the fixing portion 100F′ and the bracket 200′. The portion 200F′ of the bracket 200′ may be a protrusion protruding from a front surface of the bracket 200′.

A magnet 100M′ may be fixed to the fixing portion 100F′. The magnet 100M′ may be disposed at a rear surface of the fixing portion 100F′. The magnet 100M′ may be magnetically coupled to the bracket 200′. Accordingly, unless an external force of a predetermined magnitude or greater is applied, the fixing portion 100F′ may remain overlapped with the bracket 200′. Thus, the magnet 100M′ may minimize a tilt of the mount 100′.

First and second mounts 100A′ and 100B′ may be symmetrical in the left-right direction. Specifically, the first and second mounts 100A′ and 100B′ may be symmetrical to each other with respect to a vertical line between the first and second mounts 100A′ and 100B'. The aforementioned or following description of any one of the first and second mounts 100A′ and 100B′ may be symmetrically applied to the other.

The first mount 100A′ may be coupled to the third coupling portion 202E′ via the wire 300, and the second mount 100B′ (see FIG. 20) may be coupled to the third coupling portion 202F′ via the wire 300. The back cover (40; 40′) of the display device (1; 1′) may be coupled to the first and second mounts 100A′ and 100B′ via first and second fastening members MA and MB. In this case, the display panel (10; 10′) (see FIG. 6) of the display device (1; 1′) may have a first size. For example, a distance between the first and second fastening members MA and MB may be 600 mm.

Alternatively, the first mount 100A′ may be coupled to the second part 2022′ and the third part 2023′ of the second coupling portion 202C′ via the wire 300, and the second mount 100B′ (see FIG. 20) may be coupled to the second part 2025′ and the third part 2026′ of the second coupling portion 202D′ via the wire 300. The back cover (40; 40′) of the display device (1; 1′) may be coupled to the first and second mounts 100A′ and 100B′ via the first and second fastening members MA and MB. In this case, the display panel (10; 10′) (see FIG. 6) may have a second size. For example, a distance between the first and second fastening members MA and MB may be 400 mm.

Alternatively, the first mount 100A′ may be coupled to the first part 2021′ and the second part 2022′ of the first coupling portion 202A′ via the wire 300, and the second mount 100B′ (see FIG. 20) may be coupled to the first part 2024′ and the second part 2025′ of the first coupling portion 202B′ via the wire 300. The back cover (40; 40′) of the display device (1; 1′) may be coupled to the first and second mounts 100A′ and 100B′ via the first and second fastening members MA and MB. In this case, the display panel (10; 10′) (see FIG. 6) of the display device (1; 1′) may have a third size. For example, a distance between the first and second fastening members MA and MB may be 300 mm.

Accordingly, the bracket 200′ may be used to install the display device (1; 1′) in three sizes on the fixed object W.

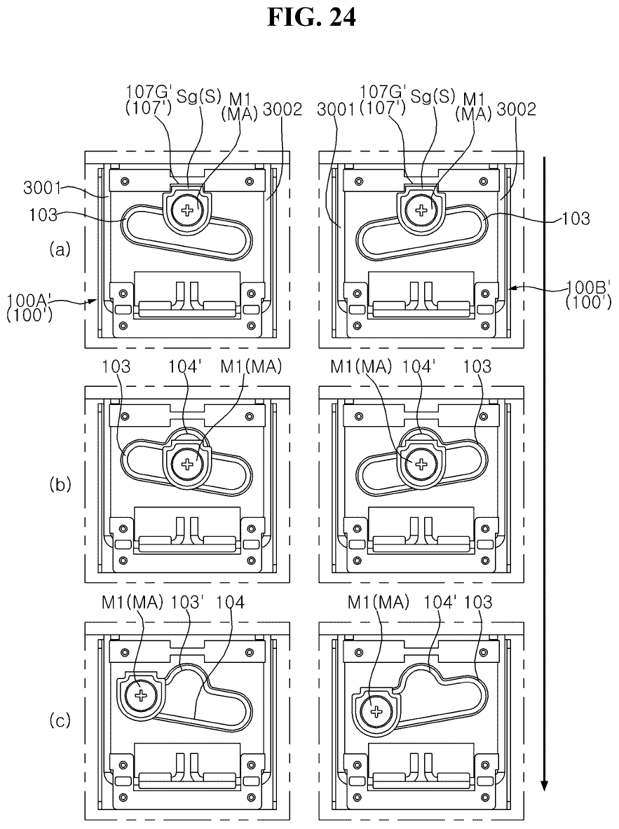

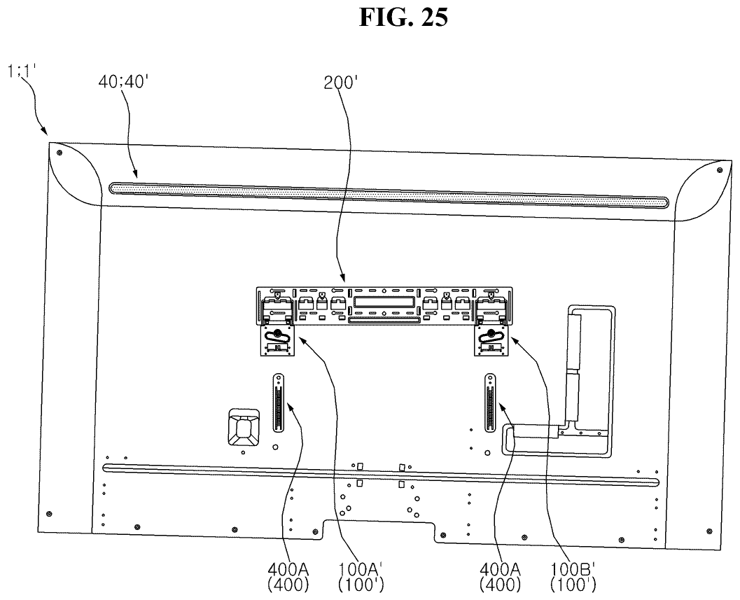

Referring to FIGS. 24 and 25, the first fastening member MA may pass through the guide hole 104′ of the first mount 100A′ and may be fastened to a display, and the second fastening member MB may pass through the guide hole 104′ of the second mount 100B′ and be fastened to the display. In this case, as the protruding portion Sg of the spacer S is inserted into the guide groove 107G′ of the guide 107′ so as to be engaged therein, rotation of the display fixed via the fastening member M may be restricted (see (a) of FIG. 24).

When a user releases a hand from the display, the first and second fastening members MA and MB may be moved from the guide holes 104′ to the slots 103 by the load of the display, and may be engaged in the slots 103 (see (b) of FIG. 2).

A user may adjust the left-right tilt of the display (see (c) of FIG. 24 and FIG. 25) by moving the first and second fastening members MA and MB in the slot 103.

Referring to FIG. 25, a spacer 400 may be positioned below the mount 100′, and may be coupled to the back cover (40; 40′). The spacer 400 may have a thickness corresponding to the mount 100′. For example, a first spacer 400A may be positioned below the first mount 100A', and a second spacer 400B may be positioned below the second mount 100B'.

Various cable(s) may be coupled to the rear of the display device (1; 1′).

Referring to FIGS. 1 to 25, a display device (1; 1′) may include: a display; a pair of mounts 100A and 100B coupled to a rear of the display; a bracket 200 positioned behind the display and spaced apart from the pair of mounts 100A and 100B; and a pair of wires 300 connecting the pair of mounts 100A and 100B and the bracket 200. The bracket 200 may include: a base 201; a pair of first coupling portions 202Aa and 202Ab protruding from the base 201 toward the display and spaced apart from each other by a first distance in a horizontal direction; and a pair of second coupling portions 202Ba and 202Bb protruding from the base 201 toward the display and spaced apart from each other by a second distance greater than the first distance in the horizontal direction. A portion of each of the pair of first coupling portions 202Aa and 202Ab may be bent in a first direction with respect to a vertical direction, and a portion of each of the pair of second coupling portions 202Ba and 202Bb may be bent in a second direction opposite to the first direction with respect to the vertical direction. The pair of wires 300 may be engaged with the pair of first coupling portions 202Aa and 202Ab or the pair of second coupling portions 202Ba and 202Bb.

A shape of the second coupling portion 202Ba may be identical to a shape of the first coupling portion 202Aa rotated 180 degrees.

The base 201 may extend in the horizontal direction. The pair of second coupling portions 202Ba and 202Bb may be spaced apart from the pair of first coupling portions 202Aa and 202Ab in a width direction of the base 201.

The pair of first coupling portions 202Aa and 202Ab may be positioned closer to a lower side of the base 201 than the pair of second coupling portions 202Ba and 202Bb. The portion of each of the pair of first coupling portions 202Aa and 202Ab may be bent upward, and the portion of each of the pair of second coupling portions 202Ba and 202Bb may be bent downward.

The bracket 200 may further include a pressed portion 201P pressed forward from a rear surface of the base 201 and positioned between the first coupling portion 202Aa and the second coupling portion 202Ba.

The bracket 200 may further include a pair of third coupling portions 202Ac and 202Ad protruding from the base 201 toward the display and spaced apart from each other by a third distance greater than the second distance in the horizontal direction. A portion of each of the pair of third coupling portions 202Ac and 202Ad may be bent in the first direction with respect to the vertical direction. The pair of wires 300 may be engaged with the pair of first coupling portions 202Aa and 202Ab, the pair of second coupling portions 202Ba and 202Bb, or the pair of third coupling portions 202Ac and 202Ad.

The base 201 may include: a first part 2011 that forms a lower portion of the base 201 and in which the pair of first coupling portions 202Aa and 202Ab and the pair of third coupling portions 202Ac 202Ad are formed; and a second part 2012 that forms an upper portion of the base 201 and in which the pair of second coupling portions 202Ba and 202Bb are formed. The first direction may be directed upward, and the second direction may be directed downward.

The bracket 200 may further include: a pair of first fixing holes 209A and 209B formed in the base 201 and spaced apart from each other in the horizontal direction; and a pair of second fixing holes 209C and 209D formed in the base 201 and spaced apart from each other in the horizontal direction. A distance between the pair of second fixing holes 209C and 209D may be greater than a distance between the pair of first fixing holes 209A and 209B.

The first fixing hole 209A and the second fixing hole 209C may extend in a length direction of the base 201.

The first coupling portion 202Aa may include: a protruding portion 2021 protruding from the base 201; and a support portion 2022 bent from the protruding portion 2021 in the first direction. A portion of the wire 300 may be positioned on the protruding portion 2021, and may be disposed between a front surface of the base 201 and the support portion 2022.

The bracket 200 may further include a pair of holders 205A and 205B coupled to a front of the base 201. The wire 300 may include: a first part 3001 positioned at a first end of the protruding portion 2021 and coupled to any one of the pair of holders 205A and 205B; a second part 3002 positioned at a second end of the protruding portion 2021 and coupled to a remaining one of the pair of holders 205A and 205B; and a third part 3003 positioned on the protruding portion 2021 and connecting the first part 3001 and the second part 3002.

The holder 205A to which the first part 3001 of the wire 300 is coupled may include: a first holder 2051; and a second holder 2052 spaced apart from the first holder 2051. The first part 3001 of the wire 300 may be inserted between the first holder 2051 and the second holder 2052. The first holder 2051 and the second holder 2052 may be elastically deformed in response to the insertion of the first part 3001 of the wire 300.

The mount 100 may include: a body 101 facing the display; a first rib 1011 bent rearward from a first side of the body 101; a second rib 1012 bent rearward from a second side of the body 101; a first guide 1071 coupled to a rear of the body 101 and adjacent to the first rib 1011; and a second guide 1072 coupled to the rear of the body 101 and adjacent to the second rib 1012. The first part 3001 of the wire 300 may be inserted between the first guide 1071 and the first rib 1011, and the second part 3002 of the wire 300 may be inserted between the second guide 1072 and the second rib 1012.

The display device (1; 1′) may further include a pair of fastening members Ma and MB coupling the pair of mounts 100A and 100B to the display. Each of the pair of mounts 100A and 100B may include a slot 103 through which a respective one of the pair of fastening members MA and MB passes.

The display may include: a back cover (40; 40′) forming a rear surface of the display; and a pair of holes formed in the back cover (40; 40′) and to which the pair of fastening members MA and MB are fastened. The pair of holes may be VESA holes.

A bracket assembly may include: a pair of mounts 100A and 100B; a bracket 200 spaced apart from the pair of mounts 100A and 100B; and a pair of wires 300 connecting the pair of mounts 100A and 100B and the bracket 200. The bracket 200 may include: a base 201; a pair of first coupling portions 202Aa and 202Ab protruding from one surface of the base 201 and spaced apart from each other by a first distance in a horizontal direction; and a pair of second coupling portions 202Ba and 202Bb protruding from the one surface of the base 201 and spaced apart from each other by a second distance greater than the first distance in the horizontal direction. A portion of each of the pair of first coupling portions 202Aa and 202Ab may be bent in a first direction with respect to a vertical direction, and a portion of each of the pair of second coupling portions 202Ba and 202Bb may be bent in a second direction opposite to the first direction with respect to the vertical direction. The pair of wires 300 may be engaged with the pair of first coupling portions 202Aa and 202Ab or the pair of second coupling portions 202Ba and 202B.

A shape of the second coupling portion 202Ba may be identical to a shape of the first coupling portion 202Aa rotated 180 degrees.

The bracket 200 may further include a pair of third coupling portions 202Ac and 202Ad protruding from the one surface of the base 201 and spaced apart from each other by a third distance greater than the second distance in the horizontal direction. A portion of each of the pair of third coupling portions 202Ac and 202Ad may be bent in the first direction with respect to the vertical direction. The pair of wires 300 may be engaged with the pair of first coupling portions 202Aa and 202Ab, the pair of second coupling portions 202Ba and 202Bb, or the pair of third coupling portions 202Ac and 202A.

The bracket 200 may further include: a pair of first fixing holes 209A and 209B formed in the base 201 and spaced apart from each other in the horizontal direction; and a pair of second fixing holes 209C and 209D formed in the base 201 and spaced apart from each other in the horizontal direction. A distance between the pair of second fixing holes 209C and 209D may be greater than a distance between the pair of first fixing holes 209A and 209B.

The bracket 200 may further include a pair of holders 205A and 205B coupled to a front of the base 201. The first coupling portion 202Aa may include: a protruding portion 2021 protruding from the base 201; and a support portion 2022 bent from the protruding portion 2021 in the first direction. The wire 300 may include: a first part 3001 positioned at a first end of the protruding portion 2021 and coupled to any one of the pair of holders 205A and 205B; a second part 3002 positioned at a second end of the protruding portion 2021 and coupled to a remaining one of the pair of holders 205A and 205B; and a third part 3003 positioned on the protruding portion 2021 and connecting the first part 3001 and the second part 3002.

A display device (1; 1′) may include: a display; a pair of mounts 100A′ and 100B′coupled to a rear of the display; a bracket 200′ positioned behind the display and spaced apart from the pair of mounts 100A′ and 100B′; and a pair of wires 300 connecting the pair of mounts 100A′ and 100B′ and the bracket 200′. The bracket 200′ may include: a base 201′; a pair of first coupling portions 202A′ and 202B′ protruding from the base 201′ toward the display and spaced apart from each other by a first distance D1′ in a horizontal direction; and a pair of second coupling portions 202C′ and 202D′ protruding from the base 201′ toward the display and spaced apart from each other by a second distance D2′ greater than the first distance D1′ in the horizontal direction.

The first coupling portion 202A′ may include a first part 2021′ and a second part 2022′ that are spaced apart from each other. The second coupling portion 202C′ may include the second part 2022′ and a third part 2023′ that are spaced apart from each other. The third part 2023′ may be positioned opposite the first part 2021′ with respect to the second part 2022′.

The display device (1; 1′) may further include: a pair of third coupling portions 202E′ and 202F′ protruding from the base 201′ toward the display and spaced apart from each other by a third distance D3′ greater than the second distance D2′ in the horizontal direction. The first coupling portion 202A′, the second coupling portion 202C′, and the third coupling portion 202E′ may each have a portion bent in one direction.

The display device (1; 1′) may further include: a fixing portion 100F′ coupled to the mount 100A′ adjacent to an upper side of the mount 100A′ and overlapping a portion of the bracket 200A′; and a protrusion 200F′ protruding from the bracket 200A′ so as to restrict movement of the fixing portion 100F′.

The display device (1; 1′) may further include: a fixing portion 100F′ coupled to the mount 100A′ adjacent to an upper side of the mount 100A′ and overlapping a portion of the bracket 200A′; and a magnet 100M′ coupled to the fixing portion 100F′ and magnetically coupled to the bracket 200′.

The display device according to the present disclosure has the following effects.

According to at least one of the embodiments of the present disclosure, it is possible to provide a structure capable of installing displays of different sizes on a fixed object such as a wall using a single bracket.

According to at least one of the embodiments of the present disclosure, it is possible to provide a bracket assembly capable of corresponding to VESA holes at various intervals.

According to at least one of the embodiments of the present disclosure, it is possible to provide a bracket capable of being secured to a fixed object such as a wall at various positions.

According to at least one of the embodiments of the present disclosure, it is possible to provide structure capable of minimizing tilting of a wire relative to a bracket.

According to at least one of the embodiments of the present disclosure, it is possible to provide a structure capable of minimizing tilting of a mount and a display relative to a bracket.

According to at least one of the embodiments of the present disclosure, it is possible to provide a structure capable of adjusting the left-right tilt of a display installed on a fixed object such as a wall.

Certain embodiments or other embodiments of the disclosure described above are not mutually exclusive or distinct from each other. Any or all elements of the embodiments of the disclosure described above may be combined or combined with each other in configuration or function.

For example, a configuration “A” described in one embodiment of the disclosure and the drawings, and a configuration “B” described in another embodiment of the disclosure and the drawings may be combined with each other. Namely, although the combination between the configurations is not directly described, the combination is possible except in the case where it is described that the combination is impossible.

The above detailed description is to be construed in all aspects as illustrative and not restrictive. The scope of the present disclosure should be determined by reasonable interpretation of the appended claims, and all changes coming within the equivalents of the present disclosure are intended to be embraced in the scope of the present disclosure.

What is claimed is:

1. A display device comprising:
a display;
a pair of mounts coupled to a rear of the display;
a bracket positioned behind the display and spaced apart from the pair of mounts; and
a pair of wires connecting the pair of mounts and the bracket,
wherein the bracket comprises:
a base;
a pair of first coupling portions protruding from the base toward the display and spaced apart from each other by a first distance in a horizontal direction; and
a pair of second coupling portions protruding from the base toward the display and spaced apart from each other by a second distance greater than the first distance in the horizontal direction,
wherein a portion of each of the pair of first coupling portions is bent in a first direction with respect to a vertical direction,
wherein a portion of each of the pair of second coupling portions is bent in a second direction opposite to the first direction with respect to the vertical direction, and
wherein the pair of wires are coupled to the pair of first coupling portions or the pair of second coupling portions.

2. The display device of claim 1, wherein a shape of the second coupling portion is identical to a shape of the first coupling portion rotated 180 degrees.

3. The display device of claim 1, wherein the base extends in the horizontal direction, and
wherein the pair of second coupling portions are spaced apart from the pair of first coupling portions in a width direction of the base.

4. The display device of claim 3, wherein the pair of first coupling portions are positioned closer to a lower side of the base than the pair of second coupling portions,
wherein the portion of each of the pair of first coupling portions is bent upward, and
wherein the portion of each of the pair of second coupling portions is bent downward.

5. The display device of claim 4, wherein the bracket further comprises a pressed portion pressed forward from a rear surface of the base and positioned between the first coupling portion and the second coupling portion.

6. The display device of claim 1, wherein the bracket further comprises a pair of third coupling portions protruding from the base toward the display and spaced apart from each other by a third distance greater than the second distance in the horizontal direction,
wherein a portion of each of the pair of third coupling portions is bent in the first direction with respect to the vertical direction, and
wherein the pair of wires are coupled to the pair of first coupling portions, the pair of second coupling portions, or the pair of third coupling portions.

7. The display device of claim 6, wherein the base comprises:
a first part that forms a lower portion of the base and in which the pair of first coupling portions and the pair of third coupling portions are formed; and
a second part that forms an upper portion of the base and in which the pair of second coupling portions are formed, and
wherein the first direction is directed upward, and the second direction is directed downward.

8. The display device of claim 1, wherein the bracket further comprises:
a pair of first fixing holes formed in the base and spaced apart from each other in the horizontal direction; and
a pair of second fixing holes formed in the base and spaced apart from each other in the horizontal direction, and
wherein a distance between the pair of second fixing holes is greater than a distance between the pair of first fixing holes.

9. The display device of claim 8, wherein the first fixing hole and the second fixing hole extend in a length direction of the base.

10. The display device of claim 1, wherein the first coupling portion comprises:
a protruding portion protruding from the base; and
a support portion bent from the protruding portion in the first direction, and
wherein a portion of the wire is positioned on the protruding portion and is disposed between a front surface of the base and the support portion.

11. The display device of claim 10, wherein the bracket further comprises a pair of holders coupled to a front of the base,
wherein the wire comprises:
a first part positioned at a first end of the protruding portion and coupled to any one of the pair of holders;
a second part positioned at a second end of the protruding portion and coupled to a remaining one of the pair of holders; and
a third part positioned on the protruding portion and connecting the first part and the second part.

12. The display device of claim 11, wherein the holder to which the first part of the wire is coupled comprises:
a first holder; and
a second holder spaced apart from the first holder,
wherein the first part of the wire is inserted between the first holder and the second holder, and
wherein the first holder and the second holder are elastically deformed in response to the insertion of the first part of the wire.

13. The display device of claim 11, wherein the mount comprises:
a body facing the display;
a first rib bent rearward from a first side of the body;
a second rib bent rearward from a second side of the body;
a first guide coupled to a rear of the body and adjacent to the first rib; and
a second guide coupled to the rear of the body and adjacent to the second rib, and
wherein the first part of the wire is inserted between the first guide and the first rib, and
wherein the second part of the wire is inserted between the second guide and the second rib.

14. The display device of claim 1, further comprising a pair of fastening members coupling the pair of mounts to the display,
wherein each of the pair of mounts comprises a slot through which a respective one of the pair of fastening members passes.

15. The display device of claim 14, wherein the display comprises:
a back cover forming a rear surface of the display; and
a pair of holes formed in the back cover and to which the pair of fastening members are fastened, and
wherein the pair of holes are VESA holes.

16. A display device comprising:
a display;
a pair of mounts coupled to a rear of the display;
a bracket positioned behind the display and spaced apart from the pair of mounts; and
a pair of wires connecting the pair of mounts and the bracket,
wherein the bracket comprises:
a base;
a pair of first coupling portions protruding from the base toward the display and spaced apart from each other by a first distance in a horizontal direction; and
a pair of second coupling portions protruding from the base toward the display and spaced apart from each other by a second distance greater than the first distance in the horizontal direction.

17. The display device of claim 16, wherein the first coupling portion comprises a first part and a second part that are spaced apart from each other,
wherein the second coupling portion comprises the second part and a third part that are spaced apart from each other, and
wherein the third part is positioned opposite the first part with respect to the second part.

18. The display device of claim 16, further comprising:
a pair of third coupling portions protruding from the base toward the display and spaced apart from each other by a third distance greater than the second distance in the horizontal direction,
wherein the first coupling portion, the second coupling portion, and the third coupling portion each have a portion bent in one direction.

19. The display device of claim 16, further comprising:
a fixing portion coupled to the mount adjacent to an upper side of the mount and overlapping a portion of the bracket; and
a protrusion protruding from the bracket so as to restrict movement of the fixing portion.

20. The display device of claim 16, further comprising:
a fixing portion coupled to the mount adjacent to an upper side of the mount and overlapping a portion of the bracket; and
a magnet coupled to the fixing portion and magnetically coupled to the bracket.
